(19) United States
(12) Patent Application Publication
(10) Pub. No.: US 2020/0114623 A1
(43) Pub. Date: Apr. 16, 2020

(54) METAL-CLAD LAMINATE AND METHOD FOR MANUFACTURING SAME

(71) Applicant: PANASONIC INTELLECTUAL PROPERTY MANAGEMENT CO., LTD., Osaka (JP)

(72) Inventors: Hiroaki TAKAHASHI, Fukushima (JP); Yoshinori MATSUZAKI, Mie (JP); Masaya KOYAMA, Mie (JP); Kiyotaka KOMORI, Mie (JP); Yusuke ITO, Mie (JP)

(73) Assignee: PANASONIC INTELLECTUAL PROPERTY MANAGEMENT CO., LTD., Osaka (JP)

(21) Appl. No.: 16/617,878

(22) PCT Filed: May 29, 2018
(86) PCT No.: PCT/JP2018/020509

§ 371 Date: Nov. 27, 2019

(30) Foreign Application Priority Data
May 31, 2017 (JP) 2017-108703

(51) Int. Cl. B32B 15/08; B32B 37/06; B32B 37/10; H05K 1/03

(52) U.S. Cl. CPC B32B 15/08; B32B 37/06; H05K 2201/0141; H05K 1/03; B32B 2457/08; B32B 37/10

(57) ABSTRACT

A metal-clad laminate provided and includes: an insulating layer containing a liquid crystal polymer; and a metal layer stacked on the insulating layer. The liquid crystal polymer has a melting point within a range from 305° C. to 320° C. The liquid crystal polymer has a loss modulus whose relationship curve with respect to temperature has two points at each of which a differential quotient is 0. A difference between values of the loss modulus at the two points being 4.0×10⁸ Pa or smaller.

### TECHNICAL FIELD

The present invention relates to a metal-clad laminate and a method for manufact the metal-clad laminate.

### BACKGROUND ART

A metal-clad laminate including an insulating layer containing a thermoplastic resin and a metal layer stacked on the insulating layer is adopted as a material for a printed wiring board such as a flexible printed wiring board. One of materials for the insulating layer is a liquid crystal polymer (see Patent Literature 1). The liquid crystal polymer has the advantage of being able to impart satisfactory high frequency properties to the printed wiring board formed from the metal-clad laminate.

### CITATION LIST

### Patent Literature

Patent Literature 1: JP 2010-221694 A

### SUMMARY OF INVENTION

It is an object of the present invention to provide: a metal-clad laminate which enables high pull strength to be realized between a metal layer and an insulating layer containing a liquid crystal polymer and which enables the insulating layer to have a satisfactory dimensional accuracy; and a method for manufacturing the metal-clad laminate.

A metal-clad laminate according to one aspect of the present invention includes an insulating layer containing a liquid crystal polymer and a metal layer stacked on the insulating layer. The liquid crystal polymer has a melting point within a range from 305° C. to 320° C. The liquid crystal polymer has a loss modulus whose relationship curve with respect to temperature has two points at each of which a differential quotient is 0. A difference between values of the loss modulus at the two points is 4.0×10⁸ Pa or smaller.

A method for manufacturing a metal-clad laminate according to one aspect of the present invention includes: stacking a film containing the liquid crystal polymer and a metal thil on each other; and hot pressing the film and the metal foil to form the insulating layer and the metal layer.

### BRIEF DESCRIPTION OF DRAWINGS

FIG. 1 is a view schematically illustrating an example of a manufacturing device for a metal-clad laminate in an embodiment of the present invention;

FIG. 2 is a graph illustrating a relationship curve between temperature and a loss modulus resulting from dynamic viscoelastic measurement of Vecstar CTQ; and

FIG. 3 is a graph illustrating a relationship curve between temperature and a loss modulus resulting from dynamic viscoelastic measurement of Vecstar CTL.

### DESCRIPTION OF EMBODIMENTS

First, a background of accomplishment of the present invention by the inventors will be described.

It is difficult in the metal-clad laminate disclosed in JP 2010-221694 A to secure a satisfactory dimensional accuracy of an insulating layer including a liquid crystal polymer while high pull strength is secured between the insulating layer and a metal foil. That is, in order to secure the high pull strength between the insulating layer and the metal foil, the insulating layer and the metal foil have to be hot-pressed under a high temperature condition, but in this case, the insulating layer tends to plastically deform, thereby degrading the dimensional accuracy.

The inventors intensively studied to find reasons for degradation of the dimensional accuracy and to overcome the degradation of the dimensional accuracy. As a result, the inventors found that when the insulating layer including the liquid crystal polymer is heated, the loss modulus of the insulating layer tends to rapidly decrease, thereby easily causing plastic deformation of the insulating layer, which may cause variations in the dimension of the insulating layer. When hot pressing is performed under a low temperature condition, the satisfactory dimensional accuracy may be secured, but in this case, the satisfactory pull strength cannot be obtained. Thus, the inventors further continued with research and development to reduce plastic deformation of the insulating layer resulting from securing of such an adhesive property and thus accomplished the present invention.

The present embodiment relates to metal-clad laminates and methods for manufacturing the metal-clad laminates. in particular, the present embodiment relates to a metal-clad laminate applicable to a material for a printed wiring board and a method for manufacturing the metal-clad laminate.

A metal-clad laminate 1 according to an embodiment of the present invention and a method for manufacturing the metal-clad laminate I will be described.

The metal-clad laminate 1 according to the present embodiment includes an insulating layer containing a liquid crystal polymer and a metal layer stacked on the insulating layer, The metal-clad laminate 1 may include two metal layers. In this case, the two metal layers are stacked on opposite surfaces of the insulating layer. The metal-clad laminate 1 may include only one metal layer. In this case, the metal layer is stacked on one surface of the insulating layer.

The liquid crystal polymer has a melting point within a range from 305° C. to 320° C. When the insulating layer is formed of film 2 formed from a liquid crystal polymer as described later, saying that the liquid crystal polymer has a melting point within a range from 305° C. to 320° C. means that the melting point of the film 2 is within a range from 305° C. to 320° C. Moreover, a relationship curve between temperature and the loss modulus of the liquid crystal polymer has two points at which a differential quotient is 0 (i.e., points at which the gradient of the relationship curve is 0), and the difference (hereinafter also referred to as ΔE″) between values of the loss modulus at the two points is 4.0×10⁸ Pa or smaller.

For measurement of the melting point of the liquid crystal polymer, the film 2 is measured by a differential scanning calorimetry (DSC) method under conditions that the temperature is within a range from 23° C. to 345° C. and the speed of temperature rise is 10° C./min, thereby obtaining a curve in which the location of a first appearing peak of adsorption of heat is defined as the melting point.

The relationship curve between the temperature and the loss modulus is obtained by dynamic viscoelastic measurement. Specifically, the relationship curve is obtained by measuring the loss modulus E″ of the liquid crystal polymer by a dynamic viscoelastic measurement (DMA) method under conditions that the temperature is within a range from 23° C. to 300° C., the speed of temperature rise is 5° C./min, a load is 20 mN, and a sample size has a width of 5 mm and a length of 10 mm. The points at which the differential quotient of the relationship curve is 0 are points occurring in the course of a continuous reduction of the loss modulus in response to a temperature rise within a temperature range from 23° C. to 300° C.

Since the metal-clad laminate 1 according to the present embodiment has the above-described configuration, high adhesion strength between the insulating layer and the metal layer is realizable. Moreover, the insulating layer can have the satisfactory dimensional accuracy, that is, the thickness of the insulating layer does not tend to vary. The reasons are probably as follows. When the liquid crystal polymer has a melting point within the range from 305° C. to 320° C. and ΔE″ is 4.0×10⁸ Pa or smaller, the loss modulus does not tend to rapidly decrease until the temperature of the insulating layer increases to approach the melting point, and therefore, the insulating layer does not easily plastically deform. As described above, the insulating layer does not easily plastically deform during the temperature rise. Therefore, also when the insulating layer and the metal layer are sufficiently bonded together in bonding the insulating layer and the metal layer together by hot pressing or the like so as to achieve high pull strength, the insulating layer does not easily plastically deform, and therefore, high dimensional accuracy may be achieved.

A configuration of the metal-clad laminate 1 will be described in further detail.

As described above, the liquid crystal polymer included in the insulating layer has a melting point within the range from 305° C. to 320° . The melting point higher than or equal to 305° C. enables the metal-clad laminate 1 to have a satisfactory heat resistance. Moreover, the melting point lower than or equal to 320° C. enables a heating temperature in a case of bonding the metal layer and the metal-clad laminate 1 together by hot pressing not to excessively increase. Therefore, it is possible to reduce plastic deformation of the insulating layer, the plastic deformation being caused due to an increase of the heating temperature. Thus, both high pull strength and a satisfactory dimensional accuracy are achieved. The melting point is more preferably within a range from 310° C. to 320° C.

As described above, ΔE″ of the liquid crystal polymer is 4.0×10⁸ Pa or smaller. Thus, the plastic deformation of the insulation layer during heating is reduced, and the satisfactory dimensional accuracy is thus achievable. ΔE″ is more preferably 3.8×10⁸ Pa or smaller. For example, ΔE″ is 1.0×10⁸ Pa or larger but is not limited to this example.

A liquid crystal polymer having such a characteristic is selectable from commercially available products. Specific examples of the film 2 formed from the liquid crystal polymer having such a characteristic include Vecstar CTQ manufactured by Kuraray Co., Ltd.

The insulating layer has a thickness of, for example, 10 μm or larger, preferably 13 μm or larger. The insulating layer has a thickness of, for example, 175 μm or smaller. The metal layer is formed of, for example, a metal foil 3. The metal foil 3 is, for example, a copper foil. The copper foil may be either an electrolytic toper foil or a rolled copper foil.

The metal layer has a thickness, for example, within a range from 2 μm to 35 μm, preferably within a range from 6 μm to 35 μm.

The metal layer has a surface which comes into contact with the insulating layer and which is preferably a rough surface. In this case, it is possible to further increase the pull strength. In particular, the surface roughness (ten point height of roughness) Rz defined in JIS B0601:1994 of the surface which comes into contact with the insulating layer is preferably 0.5 μm or greater. Moreover, it is also preferable that Rz is 2.0 μm or less, and in this case, it is possible to secure satisfactory high frequency properties of a printed wiring board manufactured from the metal-clad laminate 1.

The insulating layer has a surface facing in a thickness direction of the insulating layer, and the surface preferably has a plurality of spots. The spots may be, for example, white streaks. The proportion of the total area of the plurality of spots to the area of the surface of the insulating layer facing in the thickness direction is preferably 35% or higher, more preferably 70% or higher.

The major axis directions of the plurality of spots are preferably not aligned with each other. Saying that the major axis directions are not aligned with each other means that the major axis directions of the plurality of spots are not aligned in one direction but are oriented in various directions.

The major axis of each spot may be, hut is not particularly limited to be, larger than or equal to 5 mm and smaller than or equal to 80 mm, preferably larger than or equal to 10 mm and smaller than or equal to 70 mm. The minor axis of each spot may be, but is not particularly limited to be, larger than or equal to 0.5 mm and smaller than or equal to 20 mm, preferably larger than or equal to 1 mm and smaller than or equal to 10 mm.

Next, a method for manufacturing the metal-clad laminate 1 will be described below.

For example, the metal foil 3 and the film 2 containing the liquid crystal polymer are stacked on each other and are then subjected to hot pressing so s to manufacture a metal layer and an insulating layer, respectively. That is, the film 2 and the metal foil 3 are respectively the insulating layer and the metal layer of the metal-clad laminate 1. The metal-clad laminate 1 may thus be manufactured.

The hot pressing may be performed by, for example, an appropriate method such as platen pressing, roll pressing, or double belt pressing. The platen pressing is a method including: disposing, in a plurality of stages between two platens, a plurality of laminated bodies each including film 2 and a metal foil 3 stacked on each other; and pressing the laminated bodies while the platens are heated. The roll pressing is a method including causing a laminated body including film 2 and a metal foil 3 stacked on each other to pass between heated two rollers so that the laminated body is pressed while the laminated body is heated. The double belt pressing is a method including causing a laminated body 11 including film 2 and a metal foil 3 stacked on each other to pass between a heated two endless belts 4 so that the laminated body 11 is pressed by the endless belts 4.

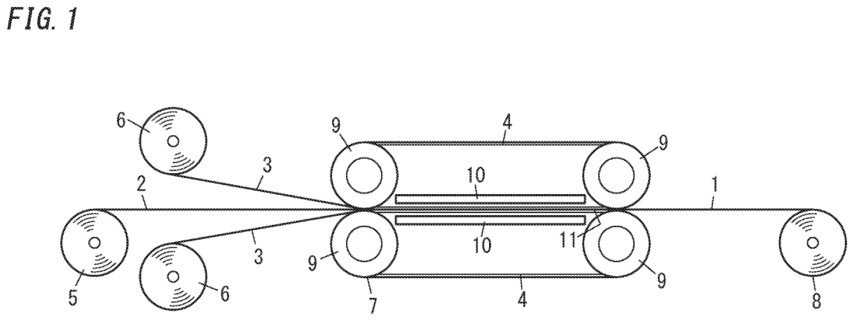

With reference to FIG. 1, a manufacturing device for manufacturing the metal-clad laminate 1 by a method including double belt pressing will be described.

The manufacturing device includes a double belt press device 7. The double belt press device 7 includes two endless belts 4 facing each other and respective thermal pressure devices 10 provided to the endless belts 4. The endless belts 4 are made of, for example, stainless steel. Each endless belt 4 is looped over two drums 9 and circles as the drums 9 rotate. The two endless belts 4 are configured to allow the laminated body 11 to pass therebetween. The laminated body 11 includes the film 2 and the metal foil 3 stacked on each other. While the laminated body 11 passes between the endless belts 4, the endless belts 4 presses the laminated body 11 with the endless belts 4 being in contact with opposite surfaces of the laminated body 11. The thermal pressure device 10 is provided inside a loop of each endless belt 4, and the thermal pressure device 10 is configured to heat the laminated body 11 via the endless belt 4 while the thermal pressure device 10 presses the laminated body 11. The thermal pressure device 10 is a hydraulic plate configured to hot press the laminated body 11 via the endless belt 4 by hydraulic pressure of, for example, a heated liquid medium. Alternatively, a plurality of pressure rollers may be installed between the two drums 9, and the drums 9 and the pressure rollers may firm the thermal pressure device 10. In this case, the pressure rollers and the drums 9 may be heated by dielectric heating or the like to heat the endless belt 4, thereby heating the laminated body 11, and the pressure rollers may press the laminated body 11 via the endless belt 4.

The manufacturing device includes a delivery apparatus 5 and two delivery apparatuses 6. The delivery apparatus 5 holds the film 2 which is elongated and which is wound in a coil form. The two delivery apparatuses 6 each hold the metal foil 3 which is elongated and which is wound in a coil form. The delivery apparatus 5 and each delivery apparatuses 6 are configured to continuously deliver the film 2 and the metal foil 3, respectively. Moreover, the manufacturing device further includes a winder 8 configured to wind in a coil form, the metal-clad laminate 1, which is elongated. The double belt press device 7 is disposed between the winder 8 and a set of the delivery apparatus 5 and the delivery apparatuses 6.

To manufacture the metal-clad laminate 1, the film 2 delivered from the delivery apparatus 5 and the two metal foils 3 delivered from the delivery apparatuses 6 are first of all supplied to the double belt press device 7. At this time, the two metal foils 3 are stacked on opposite surfaces of the film 2 to form the laminated body 11. Alternatively, to manufacture a metal-clad laminate 1 including only one metal layer, one metal foil 3 may be delivered from only one delivery apparatus 6, and thereby, the one metal foil 3 may be stacked on a surface of the film 2 to form a laminated body 11. The laminated body 11 is supplied between the two endless belts 4 of the double belt press device 7.

In the double belt press device 7, the laminated body 11 passes between the endless belts 4 in a state where the laminated body 11 is sandwiched between the two endless belts 4. The endless belts 4 circle in synchrony with the transport speed of the film 2 and the metal foil 3. While the laminated body 11 moves between the endless belts 4, the laminated body 11 is pressed and heated by the thermal pressure devices 10 via the endless belts 4. Thus, the film 2 softened or melted and the metal foils 3 are bonded together. The metal-clad laminate 1 is thus manufactured, and the metal-clad laminate 1 is derived from the double belt press device 7. The metal-clad laminate 1 is wound in a coil form by' the winder 8.

When the metal-clad laminate 1 is manufactured by a method including the double belt pressing, the endless belts 4 can press the laminated body 11 for a definite time While the endless belts 4 is in surface contact with the laminated body 11, and additionally, it is easy to heat the entirety of the laminated body 11 under the same condition. Thus, as compared to the platen pressing and the roll pressing, the heating temperature and the press-pressure are less likely to vary. This enables further increased pull strength and a further increased dimensional accuracy to be achieved.

Note that in the above description, an insulating layer is formed of one sheet of film 2, but the insulating layer may be formed of two or more sheets of film 2.

Preferably, the highest heating temperature during the hot pressing of the film 2 and the metal foil 3 is: higher than or equal to a temperature, lower than the melting point of the liquid crystal polymer by 5° C.; and lower than or equal to a temperature, higher than the melting point by 20° C. When the highest heating temperature is higher than or equal to the temperature lower than the melting point by 5° C., satisfactorily softening the film 2 during the hot pressing enables the adhesiveness between the insulating layer and the metal layer to be increased, which can further increase the pull strength. When the highest heating temperature is lower than or equal to the temperature higher than the melting point by 20° C., it is possible to reduce excessive deformation of the film 2 during the heat pressing, which can further increase the dimensional accuracy. The highest heating temperature is further preferably higher than or equal to the melting point and lower than or equal to a temperature higher than the melting point by 15° C.

When the double belt pressing is adopted to hot press the laminated body 11, a temperature difference occurring in a width direction orthogonal to a travel direction of the laminated body 11 while the laminated body 11 passes between the endless belts 4 is preferably within 10° C. In this case, the fluidity of the film 2 during the hot pressing is accordingly controllable, and therefore, it is possible to further increase the pull strength and the dimensional accuracy.

The press-pressure during the hot pressing is preferably higher than or equal to 0.49 MPa, more preferably higher than or equal to 2 MPa. In this case, it is possible to further increase the pull strength. The press-pressure is preferably lower than or equal to 5.9 MPa, more preferably lower than or equal to 5 MPa. In this case, it is possible to further increase the dimensional accuracy.

A heating and pressurizing time during the hot pressing is preferably 90 seconds or longer, more preferably 120 seconds or longer. In this case, it is possible to further increase the pull strength. The heating and pressurizing time during the hot pressing is also preferably 360 seconds or shorter, more preferably 240 seconds or shorter. In this case, it is possible to further increase the dimensional accuracy.

The insulating layer of the metal-clad laminate I has a thickness whose variable coefficient is preferably less than or equal to 3.3%. In the present embodiment, increasing the dimensional accuracy of the thickness of the insulating layer enables such a variable coefficient to be achieved. Note that the variable coefficient of the thickness is calculated from a result obtained by measuring the thickness of the insulating layer at six different locations per area of 500 mm×500 mm,

The pull strength of the metal layer from the insulating layer of the metal clad laminate 1 is preferably greater than or equal to 0.8 N/mm. In the present embodiment, improving the adhesive property between the insulating layer and the metal layer enables such a pull strength of the metal layer to be achieved. The pull strength of the metal layer is more preferably higher than or equal to 0.9 N/mm, much more preferably higher than or equal to 1.0 N/mm. Note that the pull strength of the metal layer is an average value of results obtained by measuring the pull strength of the metal layer at eight locations in the metal-clad laminate 1 by a 90-degree-pull method with AUTOGRAPH.

From the metal-clad laminate 1, a printed wiring board, such as a flexible printed wiring board, may be manufactured. The printed wiring board may be manufactured by, for example, providing conductor wiring by patterning the metal layer of the metal-clad laminate 1 by photolithography or the like. The printed wiring board may be multi-layered by a publicly known method to manufacture a multilayer printed wiring board. Alternatively, the printed wiring board may be partially multi-layered by a publicly known method to manufacture a flex-rigid printed wiring board.

### EXAMPLES

Specific examples of the present invention will hereinafter be described. Note that the present invention is not limited to the examples.

1. Manufacturing of Metal-Clad Laminate

Materials for a metal-clad laminate described below were prepared.

A laminated body including two metal foils with rough surfaces stacked on opposite surfaces of a film was hot-pressed, thereby manufacturing the metal-clad laminate. Note that the metal foil has a width dimension of 550 min, and the film has a width dimension of 530 mm.

Tables 1 and 2 show the type, the melting point, ΔE″, the average thickness, the variable coefficient of thickness, and the pull strength of film used in each of the examples and comparative examples. In the field “Type”, CTQ represents Vecstar CTQ manufactured by Kuraray Co., Ltd, CTZ represents Vecstar CTZ manufactured by Kuraray Co., Ltd, and CTF represents Vecstar CTF manufactured by Kuraray Co., Ltd. “Average thickness” is an arithmetic mean value of values obtained by measuring the thickness of the film at six different locations per area of 500 mm×500 mm with a micrometer. “Variable coefficient of thickness” is a variable coefficient calculated from a measurement result of the thickness.

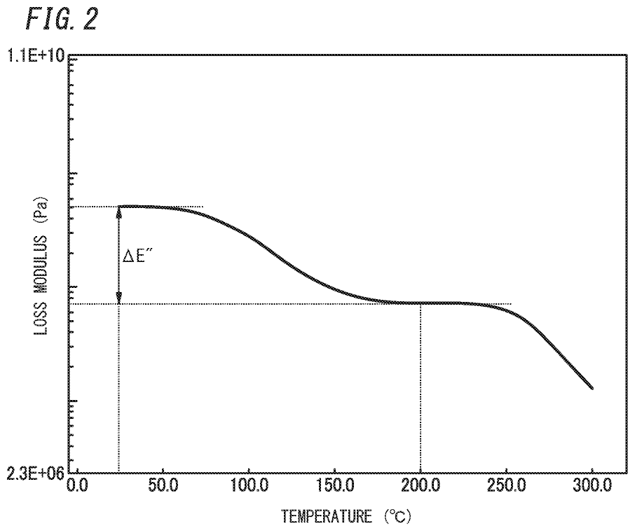

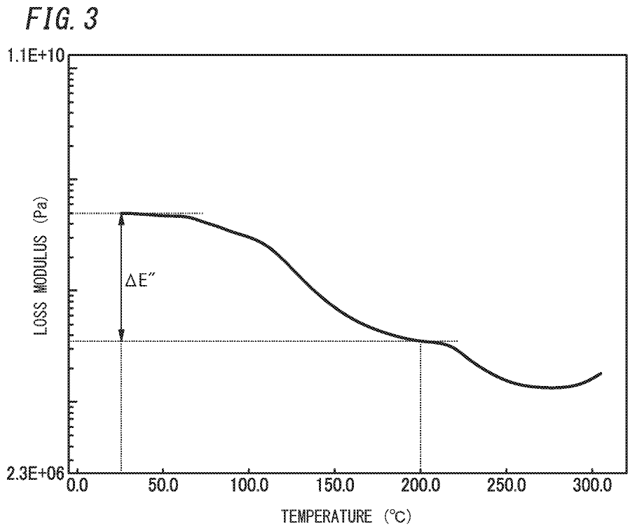

FIG. 2 shows a relationship curve between temperature and a loss modulus resulting from dynamic viscoelastic measurement of Vecstar CTQ. FIG. 3 shows a relationship curve between temperature and a loss modulus resulting from dynamic viscoelastic measurement of Vecstar CTZ.

Tables 1 and 2 also show the thickness and Rz of a rough surface of a metal foil used in each of the examples and the comparative examples.

Tables 1 and 2 also show the method, the highest heating temperature, the press-pressure, and the heating and pressurizing time of hot pressing in each of the examples and the comparative examples.

2. Evaluation Test

2-1. End Resin flow Rate

An end resin flow rate is a value which is half a value obtained by subtracting, from the width dimension of the metal-clad laminate, the width dimension of film before the film is shaped.

2-2. Variable Coefficient of Insulating Layer Thickness

From the metal-clad laminate, a metal layer was removed by an etching process, thereby obtaining an unclad board. The thickness of the unclad board was measured at six different locations per area of 500 mm×500 mm with a micrometer to obtain results, from which a variable coefficient was calculated.

2-3. Metal Layer Pull Strength

The metal layer of the metal-clad laminate was subjected to an etching process, thereby providing wiring which is linear and which has a dimension of 1 mm×200 mm. The pull strength of the wiring from the insulating layer was measured by a 90-degree-pull method. The same measurement was performed eight times to obtain results, an arithmetic mean value of which was calculated.

2-4. Variable Coefficient of Metal Layer Pull Strength

From measured values of the metal layer pull strength, a variable coefficient of the metal layer was calculated.

2-5. Spot Pattern Mode

The insulating layer of the metal-clad laminate was visually observed in the thickness direction of the insulating layer and evaluated based on the following criteria.
A: A spot pattern is found and major axis directions of spots are not aliened with each other.
B: A spot pattern is found and major axis directions of spots are aligned with an MD direction (flow direction) of film.
C: A spot pattern is found but the number of spots is small, or the spot pattern is not found.

2-6. Area Ratio of Spot

The areas of spots in a 10-cm-by-10-cm area of a surface of the insulating layer facing in the thickness direction were measured, and the percentage of the total area of the spots to the area of the 10-cm-by-10-cm area was calculated as an area ratio (%) of spot.

TABLE 1

| | | Example | | | | | | | | | |
|---|---|---|---|---|---|---|---|---|---|---|---|
| | | 1 | 2 | 3 | 4 | 5 | 6 | 7 | 8 | 9 | 10 |
| Film | Type | CTQ | CTQ | CTQ | CTQ | CTQ | CTQ | CTQ | CTQ | CTQ | CTQ |
| | Melting Point | 308 | 308 | 308 | 308 | 308 | 308 | 308 | 308 | 308 | 308 |
| | (° C.) | | | | | | | | | | |
| | ΔE″ | 3.50 | 3.50 | 3.50 | 3.50 | 3.50 | 3.50 | 3.50 | 3.50 | 3.50 | 3.50 |
| | (×10⁸ Pa) | | | | | | | | | | |
| | Thickness | 0.050 | 0.050 | 0.050 | 0.050 | 0.050 | 0.050 | 0.025 | 0.100 | 0.050 | 0.050 |
| | Average | | | | | | | | | | |
| | Value (mm) | | | | | | | | | | |
| | Variable | 2.0 | 2.0 | 2.0 | 2.0 | 2.0 | 2.0 | 2.7 | 1.7 | 2.0 | 2.0 |
| | Coefficient | | | | | | | | | | |
| | (%) of | | | | | | | | | | |
| | Thickness | | | | | | | | | | |
| Metal Foil | Thickness | 12 | 12 | 12 | 12 | 12 | 12 | 12 | 12 | 12 | 12 |
| | (μm) | | | | | | | | | | |
| | R2 (μm) of | 1.1 | 1.1 | 1.1 | 1.1 | 1.1 | 1.1 | 1.1 | 1.1 | 1.1 | 1.1 |
| | Rough | | | | | | | | | | |
| | Surface | | | | | | | | | | |
| Hot- | Method | Double | Double | Double | Double | Double | Double | Double | Double | Platen | Roll |
| Pressing | | Belt | Belt | Belt | Belt | Belt | Belt | Belt | Belt | Pressing | Pressing |
| Conditions | | Pressing | Pressing | Pressing | Pressing | Pressing | Pressing | Pressing | Pressing | | |
| | Highest | 303 | 320 | 328 | 320 | 320 | 320 | 320 | 320 | 320 | 320 |
| | Heating | | | | | | | | | | |
| | Temperature | | | | | | | | | | |
| | (° C.) | | | | | | | | | | |
| | Press- | 3.5 | 3.5 | 3.5 | 4.0 | 3.5 | 3.5 | 3.5 | 3.5 | 3.5 | 3.5 |
| | Pressure | | | | | | | | | | |
| | (Mpa) | | | | | | | | | | |
| | Heating | 140 | 140 | 140 | 140 | 360 | 90 | 140 | 140 | 5400 | 180 |
| | Pressurizing | | | | | | | | | | |
| | Time (sec) | | | | | | | | | | |
| Evaluation | End Resin | 2 | 2 | 2 | 2 | 2 | 2 | 2 | 2 | 5 | 5 |
| | Flow Rate | | | | | | | | | | |
| | (mm) | | | | | | | | | | |
| | Variable | 1.7 | 1.7 | 1.7 | 1.7 | 1.7 | 1.7 | 2.3 | 1.7 | 5.0 | 5.0 |
| | Coefficient | | | | | | | | | | |
| | (%) of | | | | | | | | | | |
| | Insulating | | | | | | | | | | |
| | Layer | | | | | | | | | | |
| | Thickness | | | | | | | | | | |
| | Metal Layer | 0.8 | 1.3 | 1.3 | 1.3 | 1.3 | 1.3 | 1.3 | 1.3 | 1.3 | 1.3 |
| | Pull Strength | | | | | | | | | | |
| | (N/mm) | | | | | | | | | | |
| | Variable | 1.7 | 1.7 | 1.7 | 1.7 | 1.7 | 1.7 | 1.7 | 1.7 | 8.0 | 8.0 |
| | Coefficient | | | | | | | | | | |
| | (%) of Metal | | | | | | | | | | |
| | Layer Pull | | | | | | | | | | |
| | Strength | | | | | | | | | | |
| | Spot Pattern | A | A | A | A | A | A | A | A | A | A |
| | Mode | | | | | | | | | | |
| | Area Ratio | 70 | 70 | 70 | 70 | 70 | 70 | 70 | 70 | 70 | 70 |
| | (%) of Spot | | | | | | | | | | |

TABLE 2

| | | Comparative Example | | | | | | |
|---|---|---|---|---|---|---|---|---|
| | | 1 | 2 | 3 | 4 | 5 | 6 | 7 |
| Film | Type | CTZ | CTZ | CTZ | CTZ | CTF | CTF | CTF |
| | Melting Point (° C.) | 335 | 335 | 335 | 335 | 280 | 280 | 280 |
| | ΔE″ (×10⁸ Pa) | 4.50 | 4.50 | 4.50 | 4.50 | 4.50 | 4.50 | 4.50 |
| | Thickness Average Value | 0.050 | 0.050 | 0.050 | 0.050 | 0.050 | 0.050 | 0.050 |
| | (mm) | | | | | | | |
| | Variable Coefficient (%) | 2.0 | 2.0 | 2.0 | 2.0 | 0.0 | 0.0 | 0.0 |
| | of Thickness | | | | | | | |
| Metal Foil | Thickness (μm) | 12 | 12 | 12 | 12 | 12 | 12 | 12 |
| | R2 (μm) of Rough | 1.1 | 1.1 | 1.1 | 1.1 | 1.1 | 1.1 | 1.1 |
| | Surface | | | | | | | |
| Hot-Pressing | Method | Double | Double | Platen | Roll | Double | Platen | Roll |
| Conditions | | Belt | Belt | Pressing | Pressing | Belt | Pressing | Pressing |
| | | Pressing | Pressing | | | Pressing | | |
| | Highest Heating | 330 | 340 | 347 | 347 | 295 | 295 | 295 |
| | Temperature (° C.) | | | | | | | |
| | Press-Pressure (Mpa) | 3.5 | 3.5 | 3.5 | 3.5 | 3.5 | 3.5 | 3.5 |
| | Heating Pressurizing | 140 | 140 | 5400 | 180 | 140 | 5400 | 180 |
| | Time (sec) | | | | | | | |
| Evaluation | End Resin Flow Rate | 2 | 2 | 10 | 10 | 2 | 10 | 10 |
| | (mm) | | | | | | | |
| | Variable Coefficient (%) | 3.3 | 3.3 | 10.0 | 10.0 | 3.3 | 10.0 | 10.0 |
| | of Insulating Layer | | | | | | | |
| | Thickness | | | | | | | |
| | Metal Layer Pull Strength | 0.7 | 1.0 | 1.3 | 1.3 | 1.0 | 1.3 | 1.3 |
| | (N/mm) | | | | | | | |
| | Variable Coefficient (%) | 3.0 | 3.0 | 8.0 | 8.0 | 3.0 | 8.0 | 8.0 |
| | of Metal Layer Pull | | | | | | | |
| | Strength | | | | | | | |
| | Spot Pattern Mode | B | B | B | B | C | C | C |
| | Area Ratio (%) of Spot | 30 | 30 | 30 | 30 | <20 | <20 | <20 |

As it is clear from the above-described embodiments, a metal-clad laminate of a first aspect of the present invention includes an insulating layer containing a liquid crystal polymer and a metal layer stacked on the insulating layer. The liquid crystal polymer has a melting point within a range from 305° C. to 320° C. The liquid crystal polymer has a loss modulus whose relationship curve with respect to temperature has two points at each of which a differential quotient is 0. A difference between values of the loss modulus at the two points is 4.0×10⁸ Pa or smaller.

The first aspect enables high pull strength to be realized between the metal layer and the insulating layer including the liquid crystal polymer and enables the insulating layer to have a satisfactory dimensional accuracy.

in a metal-clad laminate of a second aspect referring to the first aspect, the insulating layer has a thickness whose variable coefficient is less than or equal to 3.3%.

The second aspect enables the thickness of the insulating layer to be increased.

In a metal-clad laminate of a third aspect referring to the first or second aspect, pull strength of the metal layer from the insulating layer is greater than or equal to 0.8 N/mm.

The third aspect enables an adhesive property to be improved between the insulating layer and the metal layer.

In a metal-clad laminate of a fourth aspect referring to any one of first to third aspects, the insulating layer has a surface which faces in a thickness direction of the insulating layer and which has a plurality of spots, and an area ratio of the plurality of spots to the surface is greater than or equal to 35%.

In a metal-clad laminate of a fifth aspect referring to any one of first to fourth aspects, the insulating layer and the metal layer are respectively formed of a film containing the liquid crystal polymer and a metal foil, the film and the metal foil being stacked on each other and being hot-pressed. A heating temperature which is highest during the hot pressing is: higher than or equal to a temperature, lower than the melting point of the liquid crystal polymer by 5° C.; and lower than or equal to a temperature, higher than the melting point by 20° C.

The fifth aspect enables the adhesiveness to be increased between the insulating layer and the metal layer, and thus, it is possible to further increase the pull strength and to further increase the dimensional accuracy.

In a metal-clad laminate of a sixth aspect referring to any one of first to fifth aspects, the insulating layer and the metal layer are respectively formed of a film containing the liquid crystal polymer and a metal foil, the film and the metal foil being stacked on each other and being hot-pressed. The hot pressing is performed in such a manner that while a laminated body including the film and the metal foil stacked on each other is caused to pass between heated two endless belts, the laminated body is pressed by the endless belts.

The sixth aspect enables high pull strength and a high dimensional accuracy to be achieved.

A method of a seventh aspect of the present invention is a method for manufacturing the metal-clad laminate of any one of first to fourth aspects and includes stacking a film containing the liquid crystal polymer and a metal foil on each other; and hot pressing the film and the metal foil to form the insulating layer and the metal layer.

In a method of an eighth aspect referring to the seventh aspect is a method for manufacturing a metal-clad laminate, a heating temperature which is highest during the hot pressing is: higher than or equal to a temperature, lower than the melting point of the liquid crystal polymer by 5° C.; and lower than or equal to a temperature, higher than the melting point by 20° C.

The eighth aspect enables the adhesiveness to be increased between the insulating layer and the metal layer, and thus, it is possible to further increase the pull strength and to further increase the dimensional accuracy.

In a method of a ninth aspect referring to the seventh or eighth aspect is a method for manufacturing a metal-clad laminate, The hot pressing is performed in such a mariner that while a laminated body including the film and the metal foil stacked on each other is caused to pass between heated two endless belts, the laminated body is pressed by the endless belts.

The ninth aspect enables high pull strength and a high dimensional accuracy to be achieved.

### REFERENCE SIGNS LIST

1 METAL-CLAD LAMINATE

1. A metal-clad laminate, comprising:
an insulating layer containing a liquid crystal polymer; and
a metal layer stacked on the insulating layer,
the liquid crystal polymer having a point within a range from 305° C. to 320° C.,
the liquid crystal polymer having a loss modulus whose relationship curve with respect to temperature has two points at each of which a differential quotient is 0, a difference; between values of the loss modulus at the t points being 4.0×10^{s} Pa or smaller.

2. The metal-clad laminate of claim 1, the insulating layer has a thickness whose variable coefficient is less than or equal to 3.3%.

3. The metal-clad laminate of claim 1, wherein
pull strength of the metal layer from the insulating layer is greater han or equal to 0.8 N/mm.

4. The metal-clad laminate of claim 1, wherein
the insulating layer has a surface which faces in a thickness direction of the insulating layer and which has a plurality of spots, and
an area ratio of the plurality of spots to the surface is greater than or equal to 35%.

5. The metal-clad laminate of claim 1, wherein
the insulating layer and the metal layer are respectively formed of a film containing the liquid crystal polymer and a metal foil, the film and the metal foil being stacked on each other and being hot-pressed, and
a heating temperature which is highest during the hot pressing is:
higher than or equal to a temperature, lower than the melting point of the liquid crystal polymer by 5° C.; and
lower than or equalmperature, higher than the melting point by 20° C.

6. The metal-clad laminate of claim 1, wherein
the insulating layer and the metal layer are respectively formed of a film containing the liquid crystal polymer and a metal foil, the film and the metal foil being stacked on each other and being hot-pressed, and
the hot pressing is performed in such a manner that while a laminated body including the film and the metal foil stacked on each other is caused to pass between heated two endless belts, the laminated body is pressed by the endless belts.

7. A method for manufacturing the metal-clad laminate of claim 1, the method comprising
stacking a film containing the liquid crystal polymer and a metal foil on each other; and
hot pressing the film and the metal foil to form the insulating layer and the metal layer.

8. The method of claim 7, wherein,
a heating temperature which is highest during the hot pressing is:
higher than or equal to a temperature, lower than the melting point of the liquid crystal polymer by 5° C.; and
lower than or equal to a temperature, higher than the melting point by 20° C.

9. The method of claim 7, wherein,
the hot pressing is performed in such a manner that while a laminated body including the film and the metal foil stacked on each other is caused to pass between heated two endless belts, the laminated body is pressed by the endless belts.
